(19) United States
(12) Patent Application Publication
(10) Pub. No.: US 2015/0114446 A1
(43) Pub. Date: Apr. 30, 2015

(54) MULTILAYER BACK ELECTRODE FOR A PHOTOVOLTAIC THIN-FILM SOLAR CELL AND USE THEREOF FOR MANUFACTURING THIN-FILM SOLAR CELLS AND MODULES, PHOTOVOLTAIC THIN-FILM SOLAR CELLS AND MODULES CONTAINING THE MULTILAYER BACK ELECTRODE AND METHOD FOR THE MANUFACTURE THEREOF

(71) Applicant: ROBERT BOSCH GMBH, Stuttgart (DE)

(72) Inventor: Volker Probst, Berlin (DE)

(73) Assignee: Robert Bosch GmbH, Stuttgart (DE)

(21) Appl. No.: 14/389,158

(22) PCT Filed: Feb. 18, 2013
(86) PCT No.: PCT/EP2013/053144

§ 371 Date: Sep. 29, 2014

(30) Foreign Application Priority Data
Apr. 2, 2012 (DE) 102012205377.8

(51) Int. Cl. H01L 31/0224; H01L 31/046

(52) U.S. Cl. CPC H01L 31/022425; H01L 31/046
USPC 136/244; 438/73; 438/98; 136/256

(57) ABSTRACT

A multilayer back electrode for a photovoltaic thin-film solar cell, including: at least one bulk back electrode layer, at least one, ohmic, contact layer, obtained by applying at least one ply containing/essentially made of at least one metal chalcogenide, selected from molybdenum, tungsten, tantalum, cobalt, and/or niobium, and the chalcogen being selected from selenium and/or sulfur, with physical or chemical gas phase deposition while using at least one metal chalcogenide source, or obtained by applying at least one metal ply (first ply), the first ply and the bulk back electrode layer not corresponding in their composition, in the particular metal used or, if multiple metals are in the metal ply and the bulk back electrode layer, with regard to at least one, in particular all of these metals (Mo, W, Ta, Nb, and/or Co) and a metal chalcogenide ply (second ply), use of the back electrode for manufacturing thin-film solar cells and modules, photovoltaic thin-film solar cells and modules containing the back electrode, and a related method for manufacture.

### FIELD OF THE INVENTION

The present invention relates to a multilayer back electrode for a photovoltaic thin-film solar cell, the use of the multilayer back electrode for manufacturing thin-film solar cells and thin-film solar modules, photovoltaic thin-film solar cells and solar modules containing the multilayer back electrode according to the present invention, and a method for manufacturing photovoltaic thin-film solar cells and solar modules.

### BACKGROUND INFORMATION

Suitable photovoltaic solar modules include, on the one hand, crystalline and amorphous silicon solar modules and, on the other hand, so-called thin-film solar modules. In the latter, in general an IB-IIIA-VIA connection semiconductor layer, a so-called chalcopyrite semiconductor absorber layer, is used. In these thin-film solar modules, a molybdenum back electrode layer is typically applied to a glass substrate. In one method variant, this back electrode layer is provided with a precursor metal thin film, which contains copper and indium and also optionally gallium, and is subsequently reacted in the presence of hydrogen sulfide and/or hydrogen selenide and/or selenium or sulfur at elevated temperatures to form a so-called CIS or CIGS system.

To be able to reliably achieve an acceptable efficiency, particular care is generally already necessary during the selection and production of the back electrode layer.

For example, the back electrode layer is to have a high transverse conductivity, to ensure a low-loss series interconnection. Substances which migrate, for example, diffuse, out of the substrate and/or the semiconductor absorber layer should not have any influence on the quality and functional range of the back electrode layer. In addition, the material of the back electrode layer must have good adaptation to the thermal expansion behavior of the substrate and the layers lying above it, to avoid micro-cracks. Finally, the adhesion on the substrate surface should also meet all common usage requirements.

It is possible to achieve good efficiencies via the use of particularly pure back electrode material; however, disproportionately high production costs generally accompany this. In addition, the above-mentioned migration phenomena, in particular diffusion phenomena, under the typical production conditions commonly result in significant contamination of the back electrode material.

A solar cell having an absorber layer which is well implemented with regard to morphology and has good efficiency is achieved according to DE 44 42 824 C1 in that the chalcopyrite semiconductor absorber layer is doped using an element from the group sodium, potassium, and lithium in a dose of 10¹⁴ to 10¹⁶ atoms/cm² and at the same time a diffusion barrier layer is provided between the substrate and the semiconductor absorber layer. Alternatively, it is provided that an alkali-free substrate is used, if a diffusion barrier layer is to be omitted.

Bloesch et al. (Thin Solid Films 2011) provide for using a layer system made of titanium, titanium nitride, and molybdenum if a polyimide substrate film is used, to obtain good adhesion properties and a satisfactory thermal property profile. Bloesch et al. (IEEE, 2011, volume 1, issue 2, pages 194 through 199) furthermore provide for the use of flexible thin-film solar cells, the usage of a stainless steel substrate film, on which a thin titanium layer is initially applied for the purpose of improving the adhesion.

Satisfactory results were achieved using such CIGS thin-film solar cells, which were equipped with a titanium/molybdenum/molybdenum triple ply.

Improved thin-film solar cells are also sought with the discussions of WO 2011/123869 A2. The solar cell disclosed therein includes a sodium glass substrate, a molybdenum back electrode layer, a CIGS layer, a buffer layer, a layer made of intrinsic zinc oxide, and a layer made of zinc oxide doped with aluminum. A first separating trench extends over the molybdenum layer, the CIGS layer, and the powder layer; a second separating trench begins above the molybdenum layer. An insulating material is deposited in or on the first separating trench, and a front electrode layer is to be deposited diagonally onto the solar cell, including the first separating trench. In this way, thin-film solar cells having improved light yield are to be obtained. US 2004/014419 A1 is concerned with providing a thin-film solar cell, the molybdenum back electrode layer of which has improved efficiency. This is to be achieved in that a glass substrate is provided with a back electrode layer made of molybdenum, the thickness of which is not to exceed 500 nm.

It is belived to be discussed in Orgassa et al. (Thin Solid Films, 2003, volumes 431-432, pages 1987 through 1993) that greatly varying metals such as tungsten, molybdenum, chromium, tantalum, niobium, vanadium, titanium, and manganese come into question as suitable back electrode materials for thin-film solar cells.

### SUMMARY OF THE INVENTION

Therefore, the present invention is based on the object of providing back electrode systems for thin-film solar cells or solar modules, which are no longer subject to the disadvantages of the related art and which, in particular in a cost-effective and reliable way, are reproducible as thin-film solar modules having high efficiencies.

Accordingly, a multilayer back electrode for a photovoltaic thin-film solar cell has been found, including, in this sequence,
at least one bulk back electrode layer,
at least one, in particular ohmic, contact layer,
   obtained by applying at least one ply containing or essentially made of at least one metal chalcogenide, the metal of the metal chalcogenide being selected in particular from molybdenum, tungsten, tantalum, cobalt, and/or niobium, and the chalcogen of the metal chalcogenide being selected in particular from selenium and/or sulfur, with the aid of physical or chemical gas phase deposition while using at least one metal chalcogenide source or
   obtained by applying at least one metal ply (first ply), the first ply and the bulk back electrode layer not corresponding in their composition, in particular in the particular metal used or, if multiple metals are provided in the metal ply and the bulk back electrode layer, with regard to at least one, in particular all of these metals, containing or essentially made of Mo, W, Ta, Zr, Nb, and/or Co with the aid of physical gas phase deposition while using at least one metal source and treating this metal ply at temperatures greater than 300° C., which may be greater than 350° C., in a chalcogen, in particular a selenium and/or sulfur atmosphere and/or in a hydrogen chalcogenide, in particular an H₂S and/or H₂Se atmosphere, while forming a metal chalcogenide ply (second ply).

For the contact layer, in particular those specific embodiments are suitable in which the metal chalcogenide represents MSe₂, MS₂, and/or M(Se₁₋ₓ, Sₓ) where M=Mo, W, Ta, Zr, Co, or Nb and is selected in particular from the group including MoSe₂, WSe₂, TaSe₂, NbSe₂, Mo(Se₁₋ₓ, Sₓ)₂, W(Se₁₋ₓ, Sₓ)₂, Ta(Se₁₋ₓ, Sₓ)₂, and/or Nb(Se₁₋ₓ, Sₓ)₂, x assuming arbitrary values from 0 to 1.

In one refinement, it is furthermore provided that at least one conductive barrier layer is provided between the bulk electrode layer and the contact layer.

In this case, the barrier layer represents a barrier for components which migrate, in particular diffuse or are diffusible, out of the and/or via the bulk back electrode layer, and/or for components which diffuse or are diffusible out of the and/or via the contact layer. Those back electrodes in which the barrier layer represents a barrier for alkali ions, in particular sodium ions, selenium or selenium compounds, sulfur or sulfur compounds, metals, in particular Cu, In, Ga, Fe, Ni, Ti, Zr, Hf, V, Nb, Al, Ta, and/or W, and/or compounds containing alkali ions are also particularly suitable. It is provided in particular in this case that the barrier layer contains or is essentially formed of at least one metal nitride, in particular TiN, MoN, TaN, ZrN, and/or WN, at least one metal carbide, at least one metal boride, and/or at least one metal silicon nitride, in particular TiSiN, TaSiN, and/or WSiN. The metal of the metal nitrides, metal silicon nitrides, metal carbides, and/or metal borides represents titanium, molybdenum, tantalum, zirconium, or tungsten in one suitable embodiment. Such metal nitrides may be used as barrier materials in the meaning of the present invention, for example, TiN, in which the metal is deposited, with regard to nitrogen, stoichiometrically or super stoichiometrically, i.e., having nitrogen in excess.

The conductive barrier layer represents, as a bidirectionally acting barrier layer, a barrier for components, in particular dopants, which migrate, in particular diffuse or are diffusible, from the and/or via the back electrode layer and for components, in particular dopants, which diffuse or are diffusible from the and/or via the contact layer, in particular from the semiconductor absorber layer. Due to the circumstance of the presence of a barrier layer, it is possible, for example, to significantly reduce the degree of purity of the bulk back electrode material. For example, the bulk back electrode layer may be contaminated with at least one element selected from the group including Fe, Ni, Al, Ti, Zr, Hf, V, Nb, Ta, W, and/or Na and/or with compounds of the mentioned elements, without the efficiency of the thin-film solar cell or the solar module having the back electrode according to the present invention being disadvantageously impaired.

A further advantage of the use of a barrier layer with the multilayer back electrodes according to the present invention is manifested upon use in thin-film solar cells and solar modules in that the thickness of the semiconductor absorber layer, for example, the chalcopyrite or kesterite layer, may be significantly reduced in relation to conventional systems. This is because the sunlight passing the semiconductor absorber layer is very effectively reflected by the barrier layer, in particular if it is provided in the form of metal nitrides, for example, titanium nitride, or containing such metal nitrides or titanium nitrides, so that a very good quantum yield may be achieved in the course of the double passage through the semiconductor absorber layer. Due to the presence of the mentioned barrier layer in the back electrode according to the present invention or in thin-film solar cells or solar modules containing this back electrode, the average thickness of the semiconductor absorber layer may be reduced, for example, to values in the range of 0.4 μm to 1.5 μm, for example, to values in the range of 0.5 μm to 1.2 μm.

The barrier layer of the back electrode according to the present invention has, in one particularly advantageous embodiment, barrier properties, in particular bidirectional barrier properties, in relation to dopants, in particular in relation to dopants for the semiconductor absorber layer and/or from the semiconductor absorber layer, in relation to chalcogens such as selenium and/or sulfur and chalcogen compounds, in relation to the metallic components of the semiconductor absorber layer such as Cu, In, Ga, Sn, and/or Zn, and in relation to contaminants such as iron and/or nickel from the bulk back electrode layer and/or in relation to components and/or contaminants from the substrate. The bidirectional barrier properties in relation to dopants from the substrate are to prevent, on the one hand, enrichment at the interface of the back electrode or contact layer to the semiconductor absorber layer with alkali ions, for example, diffusing out of a glass substrate.

Such enrichments are known to be a reason for semiconductor layer detachments. The conductive barrier layer should therefore help to avoid adhesion problems. On the other hand, the barrier property of the dopants, diffusible or diffusing out of the semiconductor absorber, should prevent the dopant from being lost in this way to the bulk back electrode and therefore the semiconductor absorber from becoming deficient in the dopant, which would significantly reduce the efficiency of the solar cell or the solar module. This is because it is known, for example, that molybdenum back electrodes may absorb significant amounts of sodium dopant. The bidirectionally conductive barrier layer should therefore enable the requirements for suitable dosing of the dopant into the semiconductor absorber layer, to be able to achieve reproducible high efficiencies of the solar cells and solar modules.

The barrier property in relation to chalcogens should prevent them from reaching the back electrode and forming metal chalcogenide compounds therein. These chalcogenide compounds, for example, MoSe, are known to contribute to a substantial volume enlargement of the surface-proximal layer of the back electrode, which in turn results in irregularities in the layer structure and worsened adhesion. Contaminants of the bulk back electrode material such as Fe and Ni represent so-called deep imperfections for chalcopyrite semiconductors (semiconductor poisons) and are accordingly to be kept away from the semiconductor absorber layer via the barrier layer.

Suitable multilayer back electrodes according to the present invention are distinguished in that the bulk back electrode layer contains or is essentially formed of V, Mn, Cr, Mo, Ti, Co, Zr, Ta, Nb, and/or W and/or contains or is essentially formed from an alloy containing V, Mn, Cr, Mo, Ti, Co, Fe, Ni, Al, Zr, Ta, Nb, and/or W.

In this case, it may be provided in particular that the bulk back electrode layer is contaminated with at least one element selected from the group including Fe, Ni, Al, Ti, Zr, Hf, V, Nb, Ta, W, and/or Na and/or with compounds of the mentioned elements.

It has proven to be particularly suitable if the metal of the first ply and the metal of the second ply of the contact layer correspond and/or the metal of the first ply and/or the metal of the second ply of the contact layer correspond to the metal of the bulk back electrode.

Back electrodes according to the present invention, in which the contact layer, the first ply, and/or the second ply of the contact layer has/have at least one dopant for a semiconductor absorber layer of a thin-film solar cell, in particular at least one element selected from the group sodium, potassium, and lithium and/or at least one compound of these elements, which may be with oxygen, selenium, sulfur, boron, and/or halogens, for example, iodine or fluorine, and/or at least one alkali metal bronze, in particular sodium and/or potassium bronze, which may be with a metal selected from molybdenum, tungsten, tantalum, and/or niobium, are also of particular practical use. Suitable bronzes include, for example, mixed oxides or mixtures of mixed oxides and oxides, for example, Na₂MoO₂+WO. The doped contact layer is obtainable, for example, by applying the metal chalcogenide, which is admixed with the dopant, in the metal chalcogenide source.

For the case of the doping of the contact layer using dopants for the semiconductor absorber layer of a thin-film solar cell, the multilayer back electrode according to the present invention has proven itself. During the manufacture of the semiconductor absorber layer, temperatures greater than 300° C. or greater than 350° C. are regularly used. These temperatures are frequently also in the range of 500° C. to 600° C. At such temperatures dopants, such as sodium ions or sodium compounds in particular, migrate, in particular diffuse, out of the doped contact layer into the semiconductor absorber layer. A migration or diffusion into the back electrode layer does not occur due to the barrier layer.

Due to the mentioned relatively high temperatures during the processing of the semiconductor, it is advantageous for the selected layers of the multilayer back electrode, in particular the bulk back electrode and/or the conductive barrier layer, to be composed in such a way that their linear thermal coefficients of expansion are adapted to those of the semiconductor absorber and/or the substrate. Therefore, in particular the bulk back electrode and/or the barrier layer of the thin-film solar cells and solar modules according to the present invention may be composed in such a way that a linear thermal coefficient of expansion of 14*10⁻⁶ K, which may be of 9*10⁻⁶ K, is not exceeded.

In the meaning of the present invention, the physical gas phase deposition should include physical vapor deposition (PVD) coating, vapor deposition with the aid of an electron beam vaporizer, vapor deposition with the aid of a resistance vaporizer, induction vaporization, ARC vaporization, and/or sputtering (sputter coating), in particular DC or RF magnetron sputtering, in each case may be in a high vacuum, and the chemical gas phase deposition should include chemical vapor deposition (CVD), low-pressure CVD, and/or atmospheric pressure CVD.

One particularly suitable specific embodiment of the back electrode according to the present invention furthermore provides that the average thickness of the bulk back electrode layer is in the range of 50 nm to 500 nm, in particular in the range of 80 nm to 250 nm, and/or the barrier layer is in the range of 10 nm to 250 nm, in particular in the range of 20 nm to 150 nm, and/or the contact layer is in the range of 2 nm to 200 nm, in particular in the range of 5 nm to 100 nm. The total thickness of the multilayer back electrode may be to be set in such a way that the specific total resistance of the back electrode according to the present invention does not exceed 50 microohms*cm, which may be 10 microohms*cm. Ohmic losses in a module connected in series may be reduced once again under these specifications.

Those multilayer back electrodes according to the present invention, in which the bulk back electrode and the contact layer contain molybdenum or tungsten or a molybdenum or tungsten alloy, in particular molybdenum or a molybdenum alloy, or are essentially formed from molybdenum or tungsten or a molybdenum or tungsten alloy, in particular molybdenum or a molybdenum alloy, may also particularly be used.

In this context, those specific embodiments in which the bulk back electrode layer contains or is essentially formed of molybdenum and/or tungsten, in particular molybdenum, and the contact layer contains or is essentially formed of titanium, are also suitable.

The treatment of the metal ply, i.e., the first ply of the contact layer, may be carried out before and/or during the semiconductor absorber formation of a thin-film solar cell.

In one possible embodiment, the metal ply may be selected to be so thin in the case of the deposition from a metal source, for example, a molybdenum and/or tungsten source, and/or the exposure to temperature and chalcogen, for example, selenium or hydrogen selenide, may be selected to be so pronounced that the metal ply is completely converted into a single-layer metal chalcogenide layer. For this purpose, a thickness of the metal ply in the range of 2 nm to 50 nm, in particular 5 nm to 10 nm is sufficient and also advantageous. The complete conversion into a metal chalcogenide layer is achieved particularly simply and with a defined reaction stop if the metal ply for forming the contact layer has been deposited on the conductive barrier layer.

Those multilayer back electrodes in which the treatment of the metal ply (first ply) is carried out before and/or during the semiconductor absorber formation of a thin-film solar cell have also proven to be particularly suitable.

In this case, it may also be provided, inter alia, that the dopant, in particular sodium ions, is provided in the contact layer in a dose in the range of 10¹³ to 10¹⁷ atoms/cm², which may be in a dose in the range of 10¹⁴ to 10¹⁶ atoms/cm².

The object on which the present invention is based is furthermore achieved by a photovoltaic thin-film solar cell or a photovoltaic thin-film solar module, including at least one multilayer back electrode according to the present invention.

Suitable thin-film solar cells or solar modules according to the present invention include, for example, in this sequence, at least one substrate layer, at least one back electrode layer according to the present invention, at least one semiconductor absorber layer, which presses directly against the contact layer in particular, in particular a chalcopyrite or kesterite semiconductor absorber layer, and at least one front electrode.

Further specific embodiments of such thin-film solar cells and solar modules are distinguished in that at least one buffer layer, in particular at least one layer containing or essentially formed of CdS or a CdS-free layer, in particular containing or essentially made of Zn(S, OH) or In₂S₃, and/or at least one layer, containing and essentially formed of intrinsic zinc oxide and/or high-resistance zinc oxide, is provided between the semiconductor absorber layer and the front electrode.

In this case, it may also be provided that at least one conductive barrier layer is provided between the back electrode layer and the contact layer.

According to one possible embodiment of the thin-film solar cell according to the present invention or the thin-film solar module according to the present invention, the semiconductor absorber layer may represent or include a quaternary IB-IIIA-VIA chalcopyrite layer, in particular a Cu(In, Ga)Se₂-layer, a penternary IB-IIIA-VIA chalcopyrite layer, in particular a Cu(In, Ga) (Se₁₋ₓ, Sₓ)₂-layer, or a kesterite layer, in particular a Cu₂ZnSn(Se₁₋ₓ, Sₓ)₄-layer, for example, a Cu₂ZnSn(Se)₄-layer or a Cu₂ZnSn(S)₄-layer, x assuming arbitrary values from 0 to 1. The kesterite layers are generally based on an IB-IIIA-IVA-VIA structure. Cu₂ZnSnSe₄ and Cu₂ZnSnS₄ are mentioned as examples.

In one further embodiment, it may be provided that the contact layer includes at least one metal layer and at least one metal chalcogenide layer, the former being adjacent to the back electrode or adjoining thereon or being adjacent to the barrier layer or adjoining thereon, and the latter being adjacent to the semiconductor absorber layer or adjoining thereon.

Those thin-film solar cells and solar modules, in which the metal layer and the metal chalcogenide layer are based on the same metal, in particular molybdenum and/or tungsten, may also be used. In this case, the contact layer particularly may represent a metal chalcogenide layer.

Photovoltaic thin-film solar modules according to the present invention may contain at least two, in particular a plurality, of in particular monolithically integrated thin-film solar cells according to the present invention connected in series. For example, 20 to 150 or 50 to 100 thin-film solar cells according to the present invention connected in series may be provided in a thin-film solar module according to the present invention.

The specific total resistance of the multilayer back electrode according to the present invention, in one suitable embodiment, may be not be greater than 50 microohms*cm, which may be 10 microohms*cm. In this way, a low-loss monolithically integrated series circuit may be ensured.

The object on which the present invention is based is furthermore achieved by a method for manufacturing a photovoltaic thin-film solar cell according to the present invention or a photovoltaic thin-film solar module according to the present invention, including the following steps: applying the bulk back electrode layer, the barrier layer, the contact layer, the metals of the semiconductor absorber layer, and/or the dopant(s) with the aid of physical thin-film deposition methods, in particular including physical vapor deposition (PVD) coating, vapor deposition with the aid of an electron beam vaporizer, vapor deposition with the aid of a resistance vaporizer, induction vaporization, ARC vaporization, and/or sputtering (sputter coating), in particular DC or RF magnetron sputtering, in each case may be in a high vacuum, or with the aid of chemical gas phase deposition, in particular including chemical vapor deposition (CVD), low-pressure CVD, and/or atmospheric pressure CVD.

In this case, it may be provided according to the present invention that the bulk back electrode layer, the barrier layer, the contact layer, the metals of the semiconductor absorber layer, and/or the dopant(s) are applied with the aid of sputtering (sputter coating), in particular DC magnetron sputtering.

Such a method variant, in which the dopant(s) is/are applied together with at least one component of the contact layer and/or the absorber layer, in particular from a mixed or sintered target, is also advantageous. Finally, it may also be provided that the mixed or sintered target contains at least one dopant, selected from a sodium compound, a sodium-molybdenum bronze, and a sodium-tungsten bronze, in particular in a matrix component, selected from MoSe₂, WSe₂, Mo, W, copper, and/or gallium. For example, a molybdenum selenide target may be admixed with sodium sulfide as a dopant.

The present invention is accompanied by the surprising finding that with the structure of the multilayer back electrode according to the present invention, relatively thin layer thicknesses of the semiconductor absorber layer may be implemented in thin-film solar cells or solar modules, without efficiency losses having to be accepted. Higher efficiencies even frequently result using the systems according to the present invention. In this regard, it has been found that the barrier layers reflecting the sunlight contribute to further power generation. The sunlight passes the semiconductor absorber layer twice here. Furthermore, it has surprisingly been found that an improved effect also accompanies the fact that the semiconductor absorber layer, for example, based on a chalcopyrite or kesterite system, is deposited directly onto a molybdenum contact layer. This may react in this case in the subsequent semiconductor formation process at the interface to molybdenum selenide or sulfoselenide.

Furthermore, it has surprisingly been found that dopants for the semiconductor absorber layer, for example, based on sodium, when well dosed over the contact layer, i.e., originally provided in the contact layer, may be introduced into the mentioned semiconductor absorber layer. The temperatures during the formation of the semiconductor absorber layer are already sufficient for this purpose, the barrier layer also influencing the travel direction of the dopants in the direction of the semiconductor absorber layer in an assisting way. The mentioned dopants, as soon as they are provided in the semiconductor absorber layer, generally contribute to increasing the efficiency of a thin-film solar cell or solar module. In this case, it has proven to be advantageous that via the introduction via the contact layer, the amount of dopant which is finally provided in the finished product in the semiconductor absorber layer may be set very precisely. A reproducible increase of the efficiency independently of the composition of the glass and/or the bulk back electrode is first achieved in this way.

Using the systems according to the present invention, surprisingly, efficiency losses due to uncontrolled reactions of the chalcogen, in particular selenium, during the formation of the semiconductor absorber layer with the bulk back electrode may also be avoided. Because a formation of metal chalcogenides, such as molybdenum selenide, no longer occurs on the surface of the bulk back electrode, a loss of conductivity of the bulk back electrode and a lateral inhomogeneous chalcogenide formation are also avoided and therefore the formation of microcracks is suppressed. This is because a significant volume expansion frequently accompanies the chalcogenide formation. Using the systems according to the present invention it is possible, for example, to set the thickness of the individual layers and also the thickness of the overall system more precisely and reliably than in conventional thin-film systems. At the same time, the multilayer back electrodes according to the present invention enable the use of contaminated bulk back electrode material, without the efficiency of the thin-film solar cell being disadvantageously influenced. The overall costs of a thin-film solar module may be significantly reduced in this way. Furthermore, a substantially more controlled buildup of the semiconductor absorber layer is carried out using the multilayer back electrodes according to the present invention. Components of the semiconductor such as Cu, In, and/or Ga no longer migrate into the back electrode, whereby the desired mass ratio of the components forming the semiconductor absorber layer may be set more intentionally and may also be maintained.

Furthermore, the multilayer back electrode according to the present invention enables the targeted buildup of a very thin contact layer, which does not display any irregularities even when provided as a metal chalcogenide and which is not accompanied by adhesion problems.

Further features and advantages of the present invention result from the following description, in which specific embodiments of the present invention are explained as examples on the basis of schematic drawings.

### BRIEF DESCRIPTION OF THE DRAWINGS

FIG. 1 shows a schematic cross-sectional view through a partial system of a thin-film solar cell, containing a first specific embodiment of a multilayer back electrode according to the present invention.

FIG. 2 shows a schematic cross-sectional view through a partial system of a thin-film solar cell, containing a second specific embodiment of a multilayer back electrode according to the present invention.

FIG. 3 shows a schematic cross-sectional view through a partial system of a thin-film solar cell according to the present invention.

### DETAILED DESCRIPTION

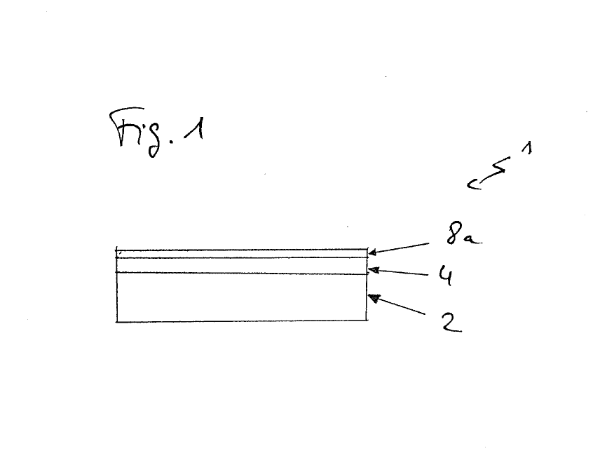

In the specific embodiment shown in FIG. 1 of a multilayer back electrode 1 according to the present invention, a bulk back electrode layer 4 made of molybdenum is provided on a substrate layer 2, for example, a glass substrate. An ohmic contact layer 8a is located applied thereon, obtained by applying at least one ply essentially made of molybdenum selenide with the aid of physical gas deposition while using at least one molybdenum selenide target. A bidirectionally acting conductive barrier layer made of, for example, tungsten nitride or titanium nitride may optionally adjoin thereon (not shown). Contact layer 8a is admixed in a specific embodiment with at least one dopant, for example, sodium ions or a sodium compound, in particular sodium sulfite or sodium sulfide. The contact layer doped in this way may be obtained in that the dopant, for example, sodium sulfite, was added to the molybdenum target. In one particularly advantageous alternative specific embodiment, the bulk back electrode and the contact layer do not correspond with respect to the metals used. For example, titanium is used for the bulk back electrode, while molybdenum or molybdenum selenide is used for the contact layer.

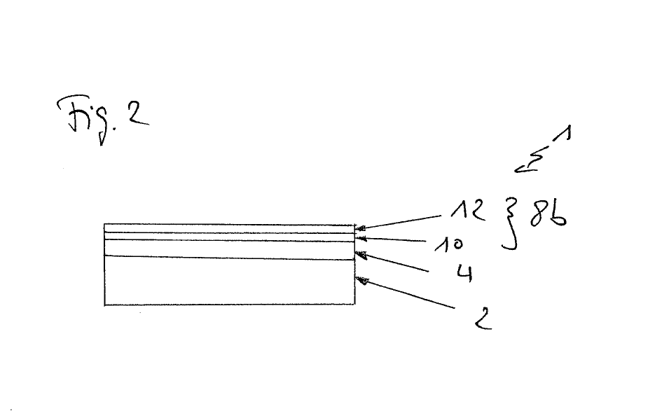

In the second specific embodiment of a multilayer back electrode 1 according to the present invention shown in FIG. 2, contact layer 8b represents a two-layer system made of a first ply 10 made of a metal, for example, molybdenum or tungsten, and a second ply 12 made of a metal chalcogenide, for example, molybdenum selenide and/or tungsten selenide, which adjoins first ply 10. At least one dopant, for example, sodium ions or a sodium compound, in particular sodium sulfite or sodium sulfide, may be also provided in contact layer 8b in this specific embodiment. In this case, the dopant may be present in the first ply and/or the second ply. This two-layer system may be obtained in that initially a metal ply is deposited with the aid of physical gas-phase deposition while using at least one molybdenum and/or tungsten source. Subsequently, the metal ply is converted at temperatures greater than 300° C., which may be greater than 350° C., in a selenium or hydrogen selenide atmosphere with the formation of two layers into the metal selenide, for example, molybdenum selenide, only partially, i.e., on the side facing away from the back electrode. Optionally (not shown), a bidirectionally acting conductive barrier layer made of tungsten nitride or titanium nitride, for example, may be provided between the bulk back electrode layer and the contact layer.

In one particularly advantageous alternative specific embodiment, the bulk back electrode and the contact layer do not correspond with respect to the metals used. For example, titanium is used for the bulk back electrode, while molybdenum or molybdenum selenide is used for the contact layer.

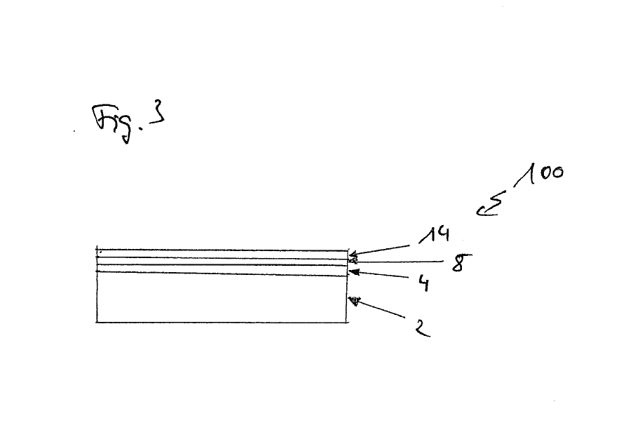

Thin-film solar cell 100 according to the present invention, which is partially shown in FIG. 3, has a substrate layer 2 made of glass, a bulk back electrode layer 4 made of, for example, Mo, W, or Ti, a contact layer 8 made of molybdenum selenide, and a chalcopyrite semiconductor absorber layer 14. This has been obtained in that initially a metal ply made of molybdenum was applied to the back electrode layer. Optionally (not shown), a bidirectionally acting conductive barrier layer made of tungsten nitride or titanium nitride, for example, may be provided between the bulk back electrode layer and the contact layer. Subsequently, the metals of the semiconductor absorber layer were applied thereon, which were then subjected to a selenium and/or sulfur atmosphere and/or a H₂S and/or H₂Se atmosphere for the purpose of forming the chalcopyrite structure. After formation of this chalcopyrite structure, the mentioned chalcogen atmosphere was maintained, which may be at temperatures greater than 350° C., with the result that the metal ply located underneath was also converted into the corresponding metal chalcogenide. In one particularly advantageous alternative specific embodiment, the bulk electrode and the contact layer also do not correspond here with respect to the metals used. For example, titanium may be used for the bulk back electrode, while molybdenum or molybdenum selenide is used for the contact layer.

The features of the present invention provided in the preceding description, the claims, and the drawings may be essential for implementing the present invention in its various specific embodiments both individually and also in any arbitrary combination.

1-28. (canceled)

29. A multilayer back electrode for a photovoltaic thin-film solar cell, comprising:
a multilayer back electrode arrangement including in the following sequence,
at least one bulk back electrode layer; and
at least one contact layer;
wherein the layer is obtained by one of:
(i) applying at least one ply containing or essentially made of at least one metal chalcogenide with physical or chemical gas phase deposition while using at least one metal chalcogenide source, and
(ii) applying at least one metal ply (a first ply), the first ply and the bulk back electrode layer not corresponding in their composition, in the particular metal used or, if multiple metals are provided in the metal ply and the bulk back electrode layer, with regard to at least one of these metals, made with physical gas phase deposition while using at least one metal source and treating this metal ply at temperatures greater than 300° C. in a chalcogen, and/or in a hydrogen chalcogenide, while forming a metal chalcogenide ply (a second ply).

30. The back electrode of claim 29, wherein the metal chalcogenide represents MSe₂, MS₂, and/or M(Se₁₋ₓ, Sₓ) where M=Mo, W, Ta, Zr, Co, or Nb and is selected in particular from the group including MoSe₂, WSe₂, TaSe₂, NbSe₂, Mo(Se₁₋ₓ, Sₓ)₂, W(Se₁₋ₓ, Sₓ)₂, Ta(Se₁₋ₓ, Sₓ)₂, and/or Nb(Se₁₋ₓ, Sₓ)₂, x assuming arbitrary values from 0 to 1.

31. The back electrode of claim 29, further comprising:
at least one conductive barrier layer, in particular a bidirectional barrier layer, which is provided between the bulk back electrode layer and the contact layer.

32. The back electrode of claim 31, wherein the barrier layer represents a barrier for alkali ions, in particular sodium ions, selenium or selenium compounds, sulfur or sulfur compounds, metals, in particular Cu, In, Ga, Fe, Ni, Al, Ti, Zr, Hf, V, Nb, Ta, and/or W, and/or compounds containing alkali ions.

33. The back electrode of claim 31, wherein the barrier layer contains or is essentially formed of at least one metal nitride, in particular TiN, MoN, TaN, ZrN, and/or WN, at least one metal carbide, at least one metal boride, and/or at least one metal silicon nitride, in particular TiSiN, TaSiN, and/or WSiN.

34. The back electrode of claim 29, wherein the bulk back electrode layer contains or is essentially formed of V, Mn, Cr, Mo, Ti, Co, Zr, Ta, Nb, and/or W and/or contains or is essentially formed from an alloy containing V, Mn, Cr, Mo, Ti, Co, Fe, Ni, Al, Zr, Ta, Nb, and/or W.

35. The back electrode of claim 29, wherein the bulk back electrode layer is contaminated with at least one element selected from the group including Fe, Ni, Al, Ti, Zr, Hf, V, Nb, Ta, W, and/or Na and/or with compounds of the mentioned elements.

36. The back electrode of claim 29, wherein the metal of the first ply and the metal of the second ply of the contact layer correspond, and/or the metal of the first ply and/or the metal of the second ply of the contact layer correspond to the metal of the bulk back electrode.

37. The back electrode of claim 29, wherein the contact layer, the first ply, and/or the second ply of the contact layer has/have at least one dopant for a semiconductor absorber layer of a thin-film solar cell, in particular at least one element selected from the group sodium, potassium, and lithium and/or at least one compound of these elements, preferably with oxygen, selenium, sulfur, boron, and/or halogens, for example, iodine or fluorine, and/or at least one alkali metal bronze, in particular sodium and/or potassium bronze, preferably with a metal selected from molybdenum, tungsten, tantalum, and/or niobium.

38. The back electrode of claim 29, wherein the physical gas phase deposition includes a physical vapor deposition (PVD) coating, vapor deposition with the aid of an electron beam vaporizer, vapor deposition with the aid of a resistance vaporizer, induction vaporization, ARC vaporization, and/or sputtering (sputter coating), in particular DC or RF magnetron sputtering, in each case preferably in a high vacuum, and the chemical gas phase deposition includes chemical vapor deposition (CVD), low-pressure CVD, and/or atmospheric pressure CVD.

39. The back electrode of claim 29, wherein the average thickness of the bulk back electrode layer is in the range of 50 nm to 500 nm, in particular in the range of 80 nm to 250 nm, and/or of the barrier layer is in the range of 10 nm to 250 nm, in particular in the range of 20 nm to 150 nm, and/or of the contact layer is in the range of 2 nm to 200 nm, in particular in the range of 5 nm to 100 nm.

40. The back electrode of claim 29, wherein the bulk back electrode and the contact layer contain molybdenum or tungsten or a molybdenum or tungsten alloy, in particular molybdenum or a molybdenum alloy, or are essentially formed from molybdenum or tungsten or a molybdenum or tungsten alloy, in particular molybdenum or a molybdenum alloy, and/or the bulk back electrode layer contains or is essentially formed of molybdenum and/or tungsten, in particular molybdenum, and the contact layer contains or is essentially formed of titanium.

41. The back electrode of claim 29, wherein the treatment of the metal ply (first ply) is carried out before and/or during the semiconductor absorber formation of a thin-film solar cell.

42. The back electrode of claim 29, wherein the bulk back electrode layer contains molybdenum and/or tungsten, in particular molybdenum, or is essentially formed from molybdenum and/or tungsten, in particular molybdenum, the conductive barrier layer contains TiN or is essentially formed from TiN, and the contact layer, which contains dopant(s) in particular, contains MoSe₂ or is essentially formed from MoSe₂.

43. The back electrode of claim 37, wherein the dopant, in particular sodium ions, is provided in the contact layer in a concentration in the range of 10¹⁴ to 10¹⁷ atoms/cm², in particular in the range of 10¹⁴ to 10¹⁶ atoms/cm².

44. A photovoltaic thin-film solar cell, comprising:
at least one multilayer back electrode including in the following sequence,
at least one bulk back electrode layer; and
at least one contact layer;
wherein the layer is obtained by one of:
(i) applying at least one ply containing or essentially made of at least one metal chalcogenide with physical or chemical gas phase deposition while using at least one metal chalcogenide source, and
(ii) applying at least one metal ply (a first ply), the first ply and the bulk back electrode layer not corresponding in their composition, in the particular metal used or, if multiple metals are provided in the metal ply and the bulk back electrode layer, with regard to at least one of these metals, made with physical gas phase deposition while using at least one metal source and treating this metal ply at temperatures greater than 300° C. in a chalcogen, and/or in a hydrogen chalcogenide, while forming a metal chalcogenide ply (a second ply).

45. The thin-film solar cell of claim 44, further comprising, in this sequence:
at least one substrate layer;
at least one back electrode including in the following sequence,
at least one bulk back electrode layer; and
at least one contact layer;
wherein the layer is obtained by one of:
(i) applying at least one ply containing or essentially made of at least one metal chalcogenide with physical or chemical gas phase deposition while using at least one metal chalcogenide source, and
(ii) applying at least one metal ply (a first ply), the first ply and the bulk back electrode layer not corresponding in their composition, in the particular metal used or, if multiple metals are provided in the metal ply and the bulk back electrode layer, with regard to at least one of these metals, made with physical gas phase deposition while using at least one metal source and treating this metal ply at temperatures greater than 300° C. in a chalcogen, and/or in a hydrogen chalcogenide, while forming a metal chalcogenide ply (a second ply);
at least one contact layer, at least one semiconductor absorber layer, which presses directly against the contact layer in particular, in particular a chalcopyrite or kesterite semiconductor absorber layer; and
at least one front electrode.

46. The thin-film solar cell claim 44, wherein at least one buffer layer, in particular at least one layer containing or essentially formed of CdS or a CdS-free layer, in particular containing or essentially made of Zn(S,OH) or In₂S₃, and/or at least one layer, containing and essentially formed of intrinsic zinc oxide and/or high-resistance zinc oxide, is provided between the semiconductor absorber layer and the front electrode.

47. The thin-film solar cell claim 44, further comprising:
at least one conductive barrier layer, in particular a bidirectional barrier layer, which is provided between the back electrode layer and the contact layer.

48. The thin-film solar cell claim 44, wherein the semiconductor absorber layer represents or includes a quaternary IB-IIIA-VIA chalcopyrite layer, in particular a Cu(In, Ga)Se₂-layer, a penternary IB-IIIA-VIA chalcopyrite layer, in particular a Cu(In, Ga) (Sₓ, Se₁₋ₓ)₂-layer, or a kesterite layer, in particular a Cu₂ZnSn(Sₓ, Se₁₋ₓ)₄-layer, for example, a Cu₂ZnSn(Se)₄-layer or a Cu₂ZnSn(S)₄-layer, x assuming arbitrary values from 0 to 1.

49. The thin-film solar cell of claim 44, wherein the contact layer includes at least one metal layer and at least one metal chalcogenide layer, the former being adjacent to the back electrode or adjoining thereon or being adjacent to the barrier layer or adjoining thereon, and the latter being adjacent to the semiconductor absorber layer or adjoining thereon.

50. A photovoltaic thin-film solar module, comprising:
at least two thin-film solar cells, which are connected;
wherein each thin-film solar cell includes a photovoltaic thin-film solar cell, including at least one multilayer back electrode, including in the following sequence,
at least one bulk back electrode layer; and
at least one contact layer;
wherein the layer is obtained by one of:
(i) applying at least one ply containing or essentially made of at least one metal chalcogenide with physical or chemical gas phase deposition while using at least one metal chalcogenide source, and
(ii) applying at least one metal ply (a first ply), the first ply and the bulk back electrode layer not corresponding in their composition, in the particular metal used or, if multiple metals are provided in the metal ply and the bulk back electrode layer, with regard to at least one of these metals, made with physical gas phase deposition while using at least one metal source and treating this metal ply at temperatures greater than 300° C. in a chalcogen, and/or in a hydrogen chalcogenide, while forming a metal chalcogenide ply (a second ply).

51. The thin-film solar cell of claim 44, wherein the solar cell is used for manufacturing photovoltaic thin-film solar modules.

52. The multilayer back electrode of claim 29, wherein the electrode is used for manufacturing photovoltaic thin-film solar cells or thin-film solar modules.

53. The multilayer back electrode of claim 37, wherein the electrode is used for doping a semiconductor absorber layer during the manufacture of a photovoltaic thin-film solar cell or a photovoltaic thin-film module,
wherein the photovoltaic thin-film solar cell includes a photovoltaic thin-film solar cell, including at least one multilayer back electrode, including in the following sequence,
at least one bulk back electrode layer; and
at least one contact layer;
wherein the layer is obtained by one of:
(i) applying at least one ply containing or essentially made of at least one metal chalcogenide with physical or chemical gas phase deposition while using at least one metal chalcogenide source, and
(ii) applying at least one metal ply (a first ply), the first ply and the bulk back electrode layer not corresponding in their composition, in the particular metal used or, if multiple metals are provided in the metal ply and the bulk back electrode layer, with regard to at least one of these metals, made with physical gas phase deposition while using at least one metal source and treating this metal ply at temperatures greater than 300° C. in a chalcogen, and/or in a hydrogen chalcogenide, while forming a metal chalcogenide ply (a second ply); and
wherein the photovoltaic thin-film solar module includes at least two thin-film solar cells, each including a photovoltaic thin-film solar cell, including at least one multilayer back electrode, including in the following sequence,
at least one bulk back electrode layer; and
at least one contact layer;
wherein the layer is obtained by one of:
(i) applying at least one ply containing or essentially made of at least one metal chalcogenide with physical or chemical gas phase deposition while using at least one metal chalcogenide source, and
(ii) applying at least one metal ply (a first ply), the first ply and the bulk back electrode layer not corresponding in their composition, in the particular metal used or, if multiple metals are provided in the metal ply and the bulk back electrode layer, with regard to at least one of these metals, made with physical gas phase deposition while using at least one metal source and treating this metal ply at temperatures greater than 300° C. in a chalcogen, and/or in a hydrogen chalcogenide, while forming a metal chalcogenide ply (a second ply).

54. A method for manufacturing a photovoltaic thin-film solar cell or a photovoltaic thin-film solar module, the method comprising:
applying a bulk back electrode layer, a barrier layer, a contact layer, metals of the semiconductor absorber layer, and/or dopant(s) with physical thin-film deposition methods, including at least one of physical vapor deposition (PVD) coating, vapor deposition with an electron beam vaporizer, vapor deposition with a resistance vaporizer, induction vaporization, ARC vaporization, and/or sputtering (sputter coating), in particular DC or RF magnetron sputtering, in each case in a high vacuum, or with the aid of chemical gas phase deposition, in particular including chemical vapor deposition (CVD), low-pressure CVD, and/or atmospheric pressure CVD;
wherein the photovoltaic thin-film solar cell includes a photovoltaic thin-film solar cell, including at least one multilayer back electrode, including in the following sequence,
at least one bulk back electrode layer; and
at least one contact layer;
wherein the layer is obtained by one of:
(i) applying at least one ply containing or essentially made of at least one metal chalcogenide with physical or chemical gas phase deposition while using at least one metal chalcogenide source, and
(ii) applying at least one metal ply (a first ply), the first ply and the bulk back electrode layer not corresponding in their composition, in the particular metal used or, if multiple metals are provided in the metal ply and the bulk back electrode layer, with regard to at least one of these metals, made with physical gas phase deposition while using at least one metal source and treating this metal ply at temperatures greater than 300° C. in a chalcogen, and/or in a hydrogen chalcogenide, while forming a metal chalcogenide ply (a second ply); and
wherein the photovoltaic thin-film solar module includes at least two thin-film solar cells, each including a photovoltaic thin-film solar cell, including at least one multilayer back electrode, including in the following sequence,
at least one bulk back electrode layer; and
at least one contact layer;
wherein the layer is obtained by one of:
(i) applying at least one ply containing or essentially made of at least one metal chalcogenide with physical or chemical gas phase deposition while using at least one metal chalcogenide source, and
(ii) applying at least one metal ply (a first ply), the first ply and the bulk back electrode layer not corresponding in their composition, in the particular metal used or, if multiple metals are provided in the metal ply and the bulk back electrode layer, with regard to at least one of these metals, made with physical gas phase deposition while using at least one metal source and treating this metal ply at temperatures greater than 300° C. in a chalcogen, and/or in a hydrogen chalcogenide, while forming a metal chalcogenide ply (a second ply).

55. The method of claim 54, wherein the bulk back electrode layer, the barrier layer, the contact layer, the metals of the semiconductor absorber layer, and/or the dopant(s) are applied with at least one of sputtering, sputter coating, and DC magnetron sputtering.

56. The method of claim 54, wherein the dopant(s), in particular selected from a sodium compound, sodium ions, a sodium-molybdenum bronze, and/or a sodium-tungsten bronze, are applied together with at least one component of the contact layer and/or the absorber layer, in particular from a mixed or sintered target.

57. The multilayer back electrode of claim 29, wherein the at least one contact layer is an ohmic, contact layer, and wherein the layer is obtained by one of:
(i) applying the at least one ply containing or essentially made of at least one metal chalcogenide, the metal of the metal chalcogenide being selected from molybdenum, tungsten, tantalum, cobalt, and/or niobium, and the chalcogen of the metal chalcogenide being selected from selenium and/or sulfur, with physical or chemical gas phase deposition while using at least one metal chalcogenide source, and
(ii) applying the at least one metal ply (a first ply), the first ply and the bulk back electrode layer not corresponding in their composition, in the particular metal used or, if multiple metals are provided in the metal ply and the bulk back electrode layer, with regard to at least one or all of these metals, containing or essentially made of Mo, W, Ta, Nb, Zr, and/or Co with physical gas phase deposition while using at least one metal source and treating this metal ply at temperatures greater than 350° C., in a chalcogen, in particular a selenium and/or sulfur atmosphere, and/or in a hydrogen chalcogenide, in particular an H₂S and/or H₂Se atmosphere, while forming a metal chalcogenide ply (a second ply).
